(19) United States
(12) Patent Application Publication
(10) Pub. No.: US 2008/0252330 A1
(43) Pub. Date: Oct. 16, 2008

(54) METHOD AND APPARATUS FOR SINGULATED DIE TESTING

(75) Inventors: Alan D. Hart, San Carlos, CA (US); Erik Volkerink, San Jose, CA (US); Gayn Erickson, San Jose, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Verigy Corporation, Fort Collins, CO (US)

(21) Appl. No.: 11/735,871

(22) Filed: Apr. 16, 2007

(51) Int. Cl. G01R 31/26

(52) U.S. Cl. 324/765

(57) ABSTRACT

In accordance with one embodiment of the invention, a method of singulated die testing can be implemented. This can be implemented by obtaining a wafer and singulating the dies into individual die pieces. The singulated dies can be arranged in a separated testing arrangement and can even combine dies from multiple wafers as part of the combined arrangement. Then, testing can be implemented on the combined test arrangement.

### CROSS-REFERENCES TO RELATED APPLICATIONS

NOT APPLICABLE

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND

Semiconductor circuits are typically manufactured using silicon wafers with multiple individual circuits fabricated on the surface of the silicon wafer. This allows mass production of circuits on individual dies which upon completion of the manufacturing process can be separated from the silicon wafer and placed in chip carriers. Thus, each silicon wafer is comprised of multiple individual dies with each die containing its own circuit.

The testing of a silicon wafer has typically involved testing the wafer while it is still in its complete wafer form. Thus, each die is tested while it is still part of the wafer. Some testing can take place after the dies are separated from the wafer; however, such testing has not involved the testing of multiple dies at the same time.

Testing of a silicon wafer is often a very involved and time-consuming process. As a result, it can account for a significant percentage of the cost involved in manufacturing a circuit. Today, most testing is implemented by testing circuits while they are still part of the silicon wafer. However, the close proximity of the individual dies often causes problems. For example, due to the necessity for coupling input and output lines to these individual dies on the wafer in order to run test routines, it is difficult condense all of the input and output lines into the desired surface area of a test interface. Thus, it is difficult to test a wafer comprised of multiple dies with a single touch-down of a test interface (also known as a probe card when used with wafers). Namely, the test interface is not able in such situations to establish the necessary points of contact or coupling with all of the dies to be tested from a single position.

For example, in some current test systems, a probe card must route many signal lines into a test head or test interface that is roughly circular with a 300 mm diameter, as that is the dimension of the wafer under test. As a result, the signal lines that are connected to the test head pins of the probe card are brought into close contact with one another. Furthermore, they are routed over a significant distance from where they originated to the test head pins. As a result, when high frequency signals are routed across the signal lines, there is significant degradation caused by the length of the signal lines (resistive, capacitive, and inductive effects) and the proximity of all the signals being bunched together. As a result, there are frequency limitations. For example, memory cannot be reliably tested with signals having a frequency greater than 150 to 200 MHz.

Another limitation on the current testing of silicon wafers is the temperature range within which silicon wafers can be tested. There is presently a limit on the temperature ranges that a die can be subjected to under testing. Namely, this range is approximately −40° C. to +80° C. The reason for this limitation is that silicon wafers are typically held to a test surface by an adhesive such as tape. The adhesive holds the wafer in place so that it does not move during testing. The physical properties of the tape, however, limit the temperature range that the silicon wafer can be subjected to. Since the tape loses adhesion at cold temperatures below −40° C. and becomes liquefied at temperatures above 80° C., the silicon wafer is often not tested above those ranges.

As noted above, testing of silicon wafers involves a great deal of time in order to sufficiently test the circuits disposed on the individual dies. This test time is a significant portion of the total cost of a circuit. A limiting factor in traditional testing is the size of the silicon wafer which dictates how many circuits can be tested. For example, a wafer having a diameter of roughly 300 mm can only have so many dies formed on the wafer. Thus, the upper limit on the number of dies that can be tested in such a situation is dictated by the number of dies on the wafer.

Thus, there is a need for a system that can remedy at least some of the drawbacks involved in testing dies fabricated on silicon wafers.

### SUMMARY

In accordance with one embodiment of the invention, a method of testing silicon wafers can be implemented by obtaining a first silicon wafer having a first plurality of dies; obtaining a second silicon wafer having a second plurality of dies; singulating said first plurality of dies from said first wafer so as to form a first set of singulated dies; singulating said second plurality of dies from said second wafer so as to form a second set of singulated dies; arranging said first set of singulated dies and said second set of singulated dies together on a support surface in a combined die arrangement, wherein said combined die arrangement comprises a total number of dies that exceeds the number of dies that were formed on said first silicon wafer; and testing said combined die arrangement as part of a single test sequence.

In accordance with another embodiment of the invention, an apparatus for testing silicon wafers can be implemented comprising a wafer singulating device configured to singulate a first wafer into singulated dies; a die placement device configured to place said singulated dies from said first wafer into a singulated die testing arrangement; wherein said wafer singulating device is further configured to singulate a second wafer into singulated dies; wherein said die placement device is further configured to place said singulated dies from said second wafer into said singulated die testing arrangement; and a testing device interface configured to provide input and output signals to said singulated die testing arrangement.

Yet another embodiment of the invention provides for an arrangement of singulated dies wherein the arrangement is comprised of a first set of singulated dies having been singulated from a first wafer; a second set of singulated dies having been singulated from a second wafer; said first set of singulated dies and said second set of singulated dies arranged in a combined die arrangement and wherein each singulated die is offset from the other singulated dies.

Still another embodiment of the invention provides for a testing device interface comprising a first interface configured to interface with a test computer; a second interface configured to interface with a plurality of singulated dies; wherein said singulated dies comprise singulated dies from a first wafer and from a second wafer arranged in a combined test pattern and wherein said second interface is configured to couple with all of the singulated dies in the combined test pattern simultaneously.

Further embodiments of the invention will be apparent from a review of the specification, figures, and claims.

### BRIEF DESCRIPTION OF THE DRAWINGS

FIG. 1 illustrates a system for testing singulated dies from multiple wafers in accordance with one embodiment of the invention.

FIG. 2 illustrates a block diagram of a computer system for implementing a computerized device in accordance with one embodiment of the invention.

FIG. 3 illustrates the singulation of multiple dies and placement in a combined singulated die test arrangement, in accordance with one embodiment of the invention.

FIG. 4 illustrates an alternative singulated die arrangement in accordance with one embodiment of the invention.

FIG. 5 illustrates a flowchart demonstrating a method of testing singulated dies in accordance with one embodiment of the invention.

FIGS. 6A and 6B illustrate a flowchart demonstrating a method of testing singulated dies in accordance with one embodiment of the invention.

### DETAILED DESCRIPTION

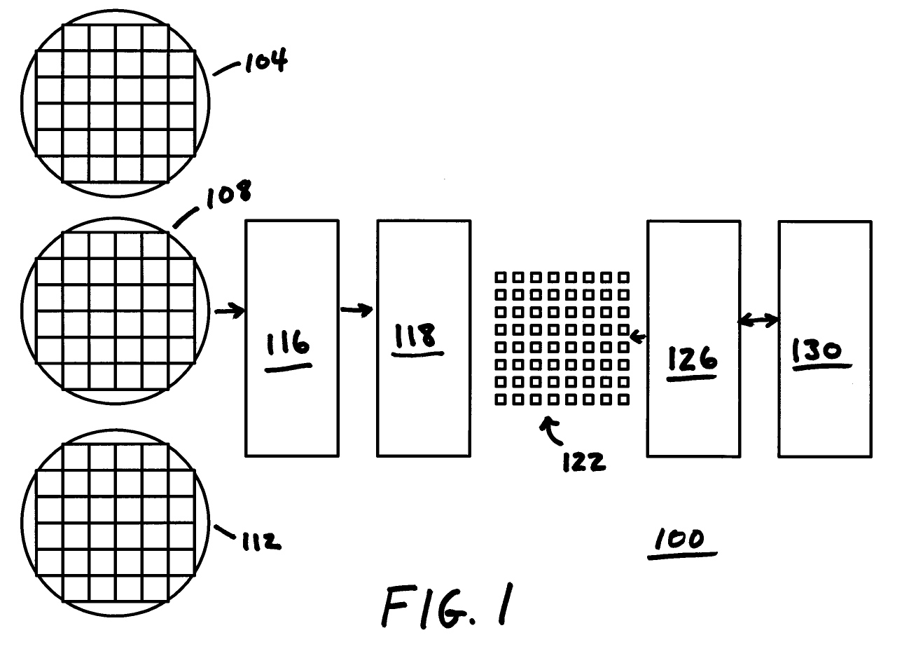

Referring now to FIG. 1, a system for testing dies in accordance with one embodiment of the invention can be seen. The system shown in FIG. 1 allows wafers to be singulated and arranged in a test arrangement. The test arrangement then allows a testing interface to be used to test the dies. Furthermore, testing of singulated dies allows dies from multiple wafers to be tested together. This can greatly facilitate the testing process and can provide alternative benefits over traditional testing methods and systems.

As one example, placement of singulated dies in a separated arrangement allows a test interface to be provided with a reduced density of signal lines. This reduced density of signal lines being routed to test pins on the surface of the test interface reduces signal interference, signal degradation, and RF effects caused by concentrating signal lines together in condensed area.

FIG. 1 shows silicon wafers 104, 108, and 112. Such silicon wafers can be provided by a manufacturer such that individual wafers are routed for example in an assembly line fashion to a testing device. FIG. 1 also shows a singulating device 116 and a die placement device 118. Furthermore, FIG. 1 shows an arrangement 122 of singulated dies that have been previously singulated from wafers and placed by the singulating device and die placement device. In addition, FIG. 1 shows a testing computer 130 which is coupled with testing interface 126. Testing interface 126 which in turn interfaces with the singulated dies.

In operation, FIG. 1 can be implemented by obtaining individual dies 104, 108 and 112, and utilizing a singulating device 116 to divide the dies from each wafer into individual singulated dies. This can be accomplished in a variety of ways such as by scribing the scribe lines between individual dies on the wafer. This allows the individual dies to be separated from the remainder of the wafer. Alternative methods of separating dies are well known in the industry. As each die is singulated, it can be grasped by a robotically controlled gripper for example that mechanically couples the die and places it in the test pattern 122. This mechanical coupling device is shown as block 118 in FIG. 1.

The test pattern 122 shown in FIG. 1 can be implemented with dies from multiple wafers. Thus, the dies shown in wafers 104 and 108 can be separated from those wafers and placed in the combined test arrangement shown as layout 122. These dies can be placed on a support surface so as to hold the dies in place. The support surface can also be enclosed so as to provide greater temperature range during testing.

The layout of the individual dies can be formed in any desirable pattern. By placing the dies with sufficient space in-between one another, the signal lines on the testing interface can also be separated from one another so as to reduce the interfering effects caused by placing signal lines in close proximity to one another. Furthermore, since the testing interface can be placed in close proximity to the testing computer, the length of the signal lines can be reduced. Block 126 represents a testing device interface. In the industry, a testing device interface for a single wafer has often been referred to as a probe card. However, interface 126 allows dies from multiple wafers to be tested at the same time. Furthermore, it is configured with a substantially greater surface area than traditional probe cards. Since the dies can be separated from one another during testing, a greater surface area is utilized. For example, rather than the 300 mm diameter surface area for a probe card, a testing interface having a square surface area could be used.

The testing interface is configured with IO hardware that allows coupling with individual dies. Typically, this is implemented by providing pins that can touch down on the contact points of the circuits configured on the dies.

Interface 126 is further coupled or interfaced with the testing computer 130. This allows the testing computer to generate a test sequence which provides input signals to the testing interface 126 and receives output signals in return. Given the flexibility provided by the singulated testing arrangement, the testing computer can actually be placed directly above the testing interface. This reduces the length of signal lines and thus reduces the RF effects caused by inductance, capacitance, and resistance of signal lines.

While FIG. 1 illustrates three wafers it should be understood that, the test pattern could be formulated from dies of a single wafer, of two wafers, or more than two wafers.

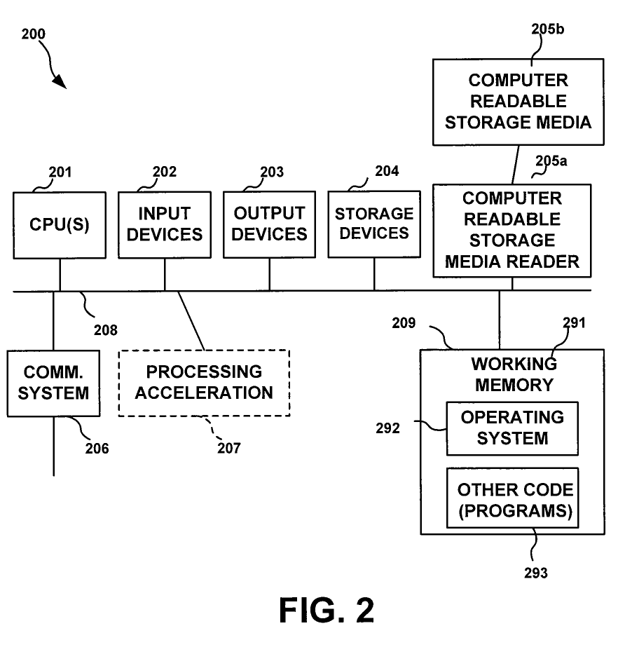

FIG. 2 broadly illustrates how individual system elements can be implemented. System 200 is shown comprised of hardware elements that are electrically coupled via bus 208, including a processor 201, input device 202, output device 203, storage device 204, computer-readable storage media reader 205a, communications system 206 processing acceleration (e.g., DSP or special-purpose processors) 207 and memory 209. Computer-readable storage media reader 205a is further coupled to computer-readable storage media 205b, the combination comprehensively representing remote, local, fixed and/or removable storage devices plus storage media, memory, etc. for temporarily and/or more permanently containing computer-readable information, which can include storage device 204, memory 209 and/or any other such accessible system 200 resource. System 200 also comprises software elements (shown as being currently located within working memory 291) including an operating system 292 and other code 293, such as programs, applets, data and the like.

System 200 has extensive flexibility and configurability. Thus, for example, a single architecture might be utilized to implement one or more servers that can be further configured in accordance with currently desirable protocols, protocol variations, extensions, etc. However, it will be apparent to those skilled in the art that embodiments may well be utilized in accordance with more specific application requirements. For example, one or more system elements might be implemented as sub-elements within a system 200 component (e.g. within communications system 206). Customized hardware might also be utilized and/or particular elements might be implemented in hardware, software (including so-called “portable software,” such as applets) or both. Further, while connection to other computing devices such as network input/output devices (not shown) may be employed, it is to be understood that wired, wireless, modem and/or other connection or connections to other computing devices might also be utilized.

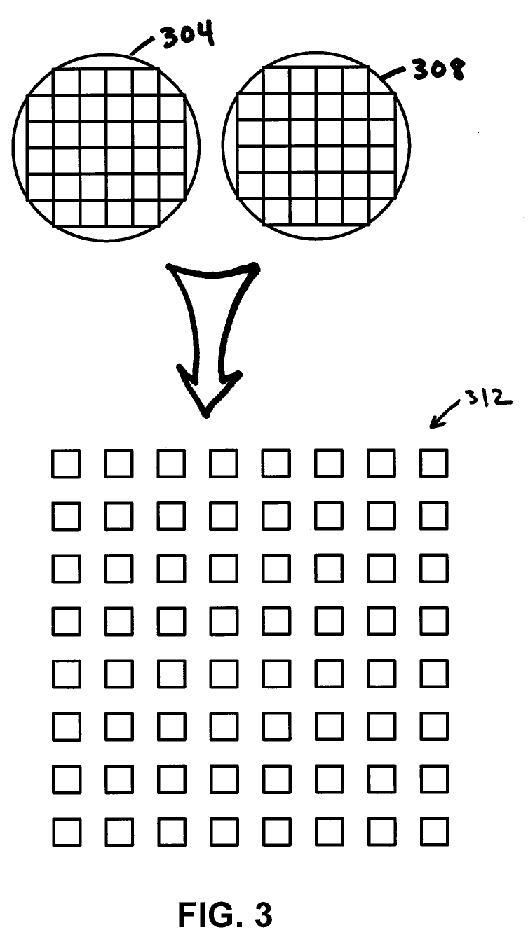

Referring now to FIG. 3, the singulation of two wafers 304 and 308 into a combined test arrangement 312 can be seen. Wafer 304 is shown comprised of 32 dies formed on the wafer. Each die includes its own individual circuit. Similarly, silicon wafer 308 includes 32 dies. While this example utilizes 32 dies, in many manufacturing processes, it is common to configure at least 512 dies on a 300 mm diameter silicon wafer. FIG. 3 shows that the silicon wafers are each singulated so that individual dies are produced and placed in a square pattern arrangement of 64 dies. As can be seen in this example, the test arrangement has a significantly greater test area than that of the original two wafers. Thus, the test interface allows greater spacing of input and output signals being routed to the surface of the test interface. As noted earlier, the separation of these input and output signals, especially when they are operated at RF frequencies, allows greater signal reliability and greater frequency range at which the dies can be tested. As a result of utilizing greater frequencies, the dies can be tested in less time. Furthermore, they can be tested for reliability over a greater frequency range.

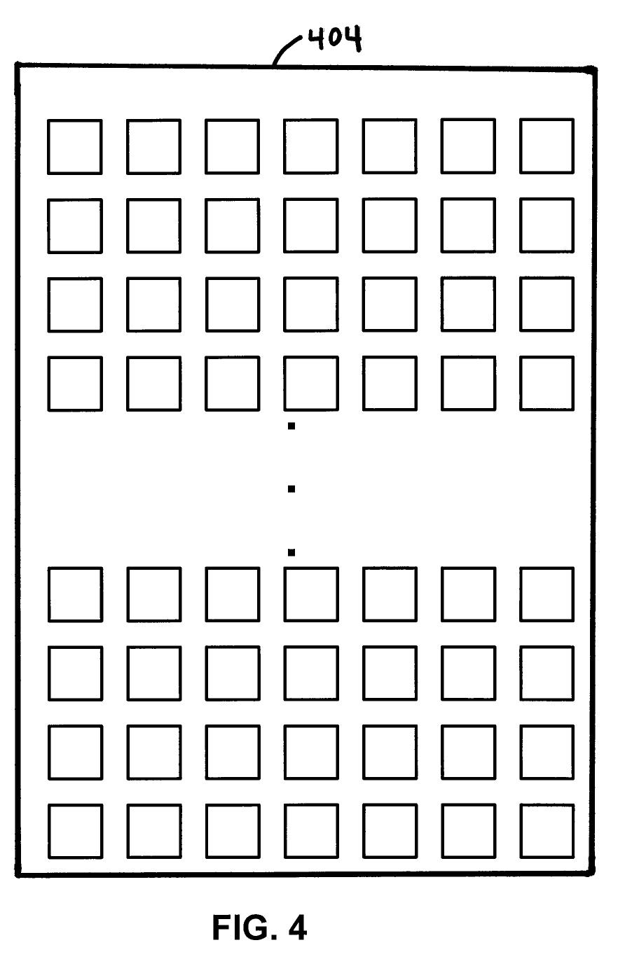

FIG. 4 illustrates another example of a combined die testing arrangement. In FIG. 4, singulated dies are placed in a pattern with additional rows that are not shown being represented by the ellipses. FIG. 4 also illustrates the outline of a testing interface 404 that can be placed directly over the combined singulated die testing arrangement. Thus, FIG. 4 is representative of the fact that a single testing interface can be placed in a position over the combined testing arrangement and not moved while still allowing all of the dies to be tested. In the industry, this is often referred to as testing utilizing a single “touchdown.” This provides greater speed in testing a group of dies in that it does not require movement of the testing interface to a second position in order to test dies that could not be tested from the first position. While power requirements may not permit it or deter one from doing so, the testing interface shown in FIG. 4 can also allow multiple dies to be tested in parallel simultaneously. Moreover, it allows multiple dies from multiple wafers to be tested in parallel. It is recognized that to do so would typically require significant power usage. Therefore, one may choose to not test simultaneously, but still test the combined arrangement without needing to reposition the testing interface relative to the die arrangement.

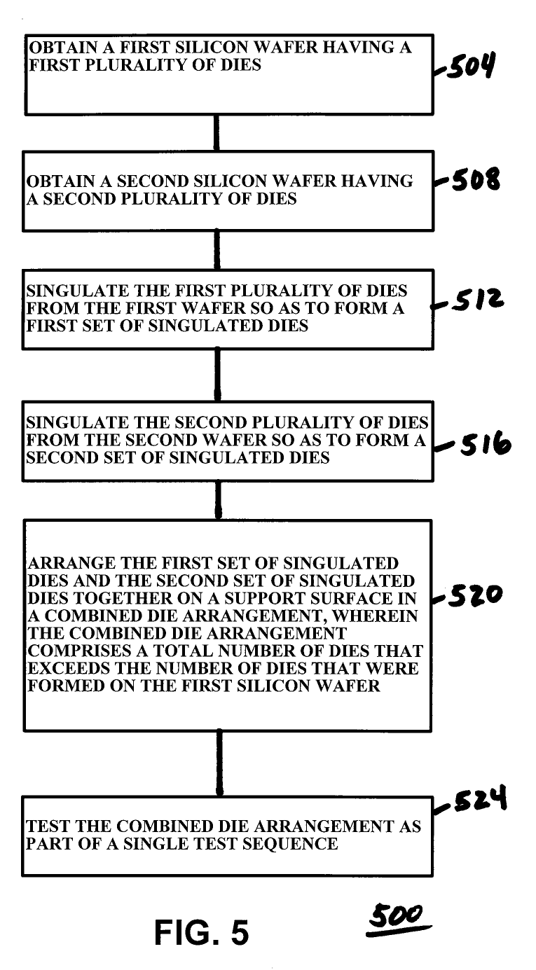

Referring now to FIG. 5, flowchart 500 illustrates an example of testing singulated dies. In block 504, a first silicon wafer is obtained. The silicon wafer is configured with multiple dies. Similarly, in block 508, a second silicon wafer having a second group of dies is obtained. The first silicon wafer is singulated so as to separate individual dies from the first wafer as shown in block 512. Similarly, block 516 shows that the dies on the second silicon wafer can also be singulated. In block 520, the first and second set of singulated dies are arranged together on a support surface in a combined die arrangement. The combined die arrangement is made up of a total number of dies that exceeds the number of dies available on a single one of the wafers. Thus, the combined die arrangement allows testing of more dies than could be tested by testing a single silicon wafer. In block 524, the combined die arrangement is tested as part of a single test sequence.

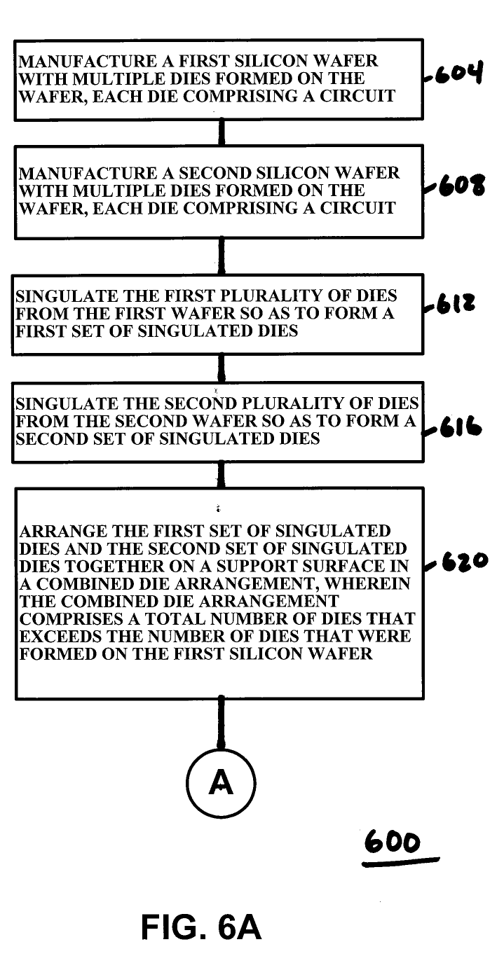

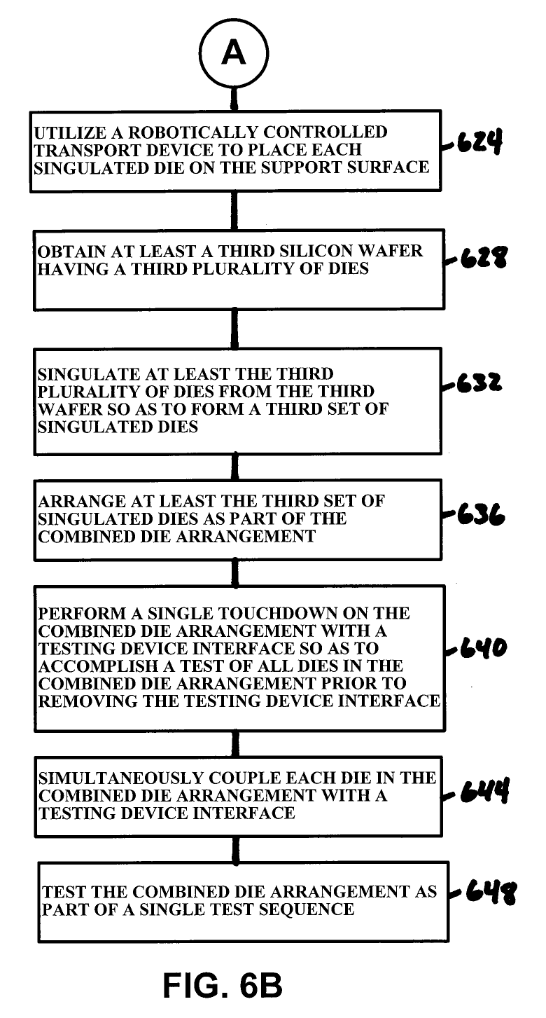

A more detailed example of singulated die testing can be seen in flowchart 600 illustrated in FIGS. 6A and 6B. In block 604, a first silicon wafer is manufactured with multiple dies formed on the wafer. Each of the dies has a circuit, such as an integrated circuit. However, it is not necessary that each circuit be the same. Similarly, in block 608, a second silicon wafer is manufactured having multiple dies on it. In block 612, the first silicon wafer is singulated so as to form a first set of singulated dies. Similarly, in block 616, the second silicon wafer is singulated so as to form a second set of singulated dies. The first set of singulated dies and the second set of singulated dies are arranged together on a support surface in a combined die arrangement, as shown by block 620. The combined die arrangement is comprised of a total number of dies that exceeds the number of dies that were formed on the first silicon wafer. In block 624, a transport device, such as a robotically controlled arm, can be utilized to mechanically couple a singulated die and place it on a support surface. For example, pick-and-place mechanisms are well known in the industry.

Block 628 illustrates that even a third silicon wafer having multiple dies disposed on it can be obtained. Furthermore, the third silicon wafer can be singulated as shown in block 632 so as to form a third set of singulated dies. It should be understood that one or more silicon wafers can be singulated and combined in a combined test arrangement in accordance with embodiments of the invention. The use of dies from additional wafers merely expands the test area and can be addressed with a larger test interface. In block 636, the third set of singulated dies can be arranged as part of the combined die arrangement.

In accordance with one embodiment of the invention, a single touch down on the combined die arrangement can be utilized to test all of the dies in the combined die arrangement. Heretofore, this has been difficult to do with traditional wafer testing. Namely, this has been due to the difficulties in condensing all of the input and output signals into an area sufficient to test a silicon wafer. In accordance with one embodiment of the invention, the spacing of the singulated dies allows input and output signals to be space apart on the testing interface without causing serious signal degradation or interference. Thus, a larger test interface can be configured to cover the larger surface area of the singulated die arrangement and a single touch down can be performed. The testing sequence can be implemented without moving or removing the testing device interface once it is placed into a testing position. In block 644, one could even simultaneously couple each die in the combined die arrangement with the testing device interface. In such a situation, electrical coupling could be implemented simultaneously so as to test each die simultaneously. Alternatively, in order to reduce power requirements, individual dies can be tested in sequence or in blocks so as to reduce power requirements. In block 648, the combined die arrangement is tested as part of a single test sequence.

The embodiments disclosed above can be further enhanced in accordance with one or more of the following. For example, extreme temperature range testing of wafer dies may be implemented. There is presently a limit on the temperature ranges that a die can be subjected to under testing. Namely, this range is approximately −40 degrees C. to +80 degrees C. This problem is introduced by the physical properties of the tape that is used to adhere to the wafer. At cold temperatures the tape loses adhesion and at high temperatures the tape becomes liquefied. By singulating the dies and utilizing a mechanism such as pulling a vacuum through a porous plate, the die can be held in place during test without the use of tape. This allows greater temperature ranges such as −55 C to +150 C. Furthermore, greater temperature ranges can be achieved by encapsulating the dies in a chamber rather than just heating them from a chuck, as is currently done.

In addition, it is becoming more common to polish dies so as to decrease their thickness prior to being placed in packages. This is necessary, for example, when multiple dies are stacked in packages. Wafers can be thinned from 250 microns thick to 70 microns thick, for example. The act of polishing can cause mechanical defects in the circuits, such as mechanical stress in the silicon crystalline. In the past, the testing occurred before the act of polishing and these mechanical defects were not caught. In accordance with one enhancement, die can now be tested after they have been singulated and polished but before being placed in a package. This allows defects due to polishing to be tested for.

Wafers are currently cut by equipment that is roughly accurate to within +/−100 microns. This is sufficient for placing a die in a package where there is tolerance for contacting the bonding pads. However, when singulated die testing is used, the testing interface will need to touch down on the dies at precise locations—e.g., no more than 10 microns away from the target location. If the testing interface pin does not touch down on the correct spot, then there may be no electrical connection or misconnection for purposes of inputting and outputting test signals. Generally, this can be overcome by laying out dies in a testing layout with a very limited tolerance (e.g., 10 microns) from the desired locations. Alternatively, singulated dies can be grabbed with a mechanical coupling device. Then the die can be optically viewed to locate a reference point on the die using pattern recognition. Then, the die can be placed in the exact location by knowing where that optically recognized location of the die should be located on the die layout. Similarly, the die may be fabricated with reference points that can be used to align the dies.

Presently, die testing cannot take place at sufficiently extreme temperatures. In accordance with one enhancement, the singulated die arrangement can be placed in a temperature controlled chamber. The temperature range can then be varied over a wide range. The testing interface can form the top of the test chamber in such a situation, in accordance with one variation.

There appears to be no commercially available handling mechanism currently in existence that takes a singulated die and places it in a test layout and then removes it from the test layout. Rather, the singulated dies are normally just placed in die carriers after scribing and the die carriers are taken away. In accordance with embodiments of the invention described above, a pick and place device that can remove singulated dies from a wafer and place them on a test layout prior to testing and then remove them from the test layout after testing can be implemented.

Due to the precision that is necessary in touching down on the dies at the precise locations for test purposes, it is important that the dies be aligned properly. This problem can be addressed in accordance with one enhancement by utilizing pre-fabricated die trays with depressions that the dies can be placed in. Assuming that the outer dimensions of the dies are cut precisely, the placement of the dies in the depressions and a slight suction applied from beneath the dies will allow the dies to be aligned correctly by the dimensions of the depressions. This is analogous to silverware being placed in silverware trays.

Once dies are aligned on a layout, one would want to make sure that they do not move out of position during singulated die testing. This can be solved utilizing a porous die carrier that allows a vacuum to be pulled from beneath the die. This would allow the dies to be held in position without damaging the thin dies.

One enhancement may be implemented particular to flash memory. Flash memory is referred to as a non-terminating device. As a result, an input signal to a flash memory cell will be reflected just as if a signal on a transmission line did not have a matching terminating impedance at the end of the transmission line. This condition is exacerbated by test systems that utilize long test lines to test the flash memory. This problem can be addressed by utilizing a system in which the signal lines are very short. That can be accomplished with the new testing interface of this system in which the signal lines are, for example, 2 inches rather than the traditional 2 feet.

As noted above, the precise placement of a singulated die is important to allow the probe pins to touch down on the precise target locations. The thin and lightweight dies containing metallization layers can be moved with magnetic forces. Such magnetic forces could be used to pull a coarsely positioned die into a tray well. In addition, a die could be designed to be manufactured with a significant metal portion to allow the die to be more responsive to a magnetic field.

Placement of an entire field of singulated dies may take a period of time. This placement time could be used to begin testing on already placed dies. Thus, one could perform multiple processes on the field of dies at the same time. A long thin testing interface could be used to begin testing columns of dies in the singulated die testing layout as the remaining dies are being placed on the testing layout. Then, as a column is finished being tested, completely tested dies could be picked off of the layout.

In testing a whole (non-singulated) wafer, a defective pin on the testing interface will prevent at least one die on the wafer from being tested. There is no way to get around the defective pin. This either wastes those untested dies or causes downtime to fix the testing interface. In accordance with present embodiments of the invention, this problem can be overcome. If the new testing interface (e.g., 1 meter on edge) has a defective pin, that defective pin can be identified and the subsequent layout process can simply avoid placing dies underneath the defective pin. This allows an on-the-fly determination of where to put dies in the layout so that all dies are tested and no downtime is required to fix the testing interface.

The placement of dies will be a time consuming process. There is a need for methods that will speed up the process of placing the dies in the testing layout. This can be addressed in accordance with one enhancement by using a multi-headed picker to pickup and place multiple dies at the same time. This will allow fewer arm movements from the die tray to the testing layout.

Precise placement of dies for testing will be challenging. Thus, there is a need for a system that can locate the dies precisely so that test procedures will not fail. In accordance with one embodiment, the dies can be cut to have a constant width and then each die placed on the layout with coarse precision. Two L-shaped mechanical contacts can then be used to push the dies from opposite corners into proper placement using predetermined coordinates for final stopping points of the L shaped contacts.

In order to align the dies precisely, it is beneficial to cut the dies so that the outer border of the die is known with some small degree of error. Current cutting techniques do not provide the precision cutting necessary. One option would be to utilize a laser to cut the dies with a high degree of precision.

Alignment of dies will be challenging and time consuming. There are benefits to be gained from testing dies after they have been removed entirely from the wafer, but there are also time penalties. Thus, in accordance with one enhancement, strips of dies can be cut from a wafer but not completely singulated as individual dies. This will speed up the process of placing the die strips and should allow alignment in only one dimension.

When dies are eventually placed in a test layout, it is important that the dies not be moved out of position. One solution is to provide a carrier with sticky tape to receive the dies so as to prevent the dies from being moved once they adhere to the tape. However, in some instances it is necessary to test dies from below where, for example, vias are located. When dies are secured by sticky tape, these connection points will be obstructed. This problem can be addressed by punching conducting wires through the tape to achieve backside conductance.

While various embodiments of the invention have been described as methods or apparatus for implementing the invention, it should be understood that the invention can be implemented through code coupled to a computer, e.g., code resident on a computer or accessible by the computer. For example, software and databases could be utilized to implement many of the methods discussed above. Thus, in addition to embodiments where the invention is accomplished by hardware, it is also noted that these embodiments can be accomplished through the use of an article of manufacture comprised of a computer usable medium having a computer readable program code embodied therein, which causes the enablement of the functions disclosed in this description. Therefore, it is desired that embodiments of the invention also be considered protected by this patent in their program code means as well. Furthermore, the embodiments of the invention may be embodied as code stored in a computer-readable memory of virtually any kind including, without limitation, RAM, ROM, magnetic media, optical media, or magneto-optical media. Even more generally, the embodiments of the invention could be implemented in software, or in hardware, or any combination thereof including, but not limited to, software running on a general purpose processor, microcode, PLAs, or ASICs.

It is also envisioned that embodiments of the invention could be accomplished as computer signals embodied in a carrier wave, as well as signals (e.g., electrical and optical) propagated through a transmission medium. Thus, the various information discussed above could be formatted in a structure, such as a data structure, and transmitted as an electrical signal through a transmission medium or stored on a computer readable medium.

It is also noted that many of the structures, materials, and acts recited herein can be recited as means for performing a function or steps for performing a function. Therefore, it should be understood that such language is entitled to cover all such structures, materials, or acts disclosed within this specification and their equivalents.

It is thought that the apparatuses and methods of the embodiments of the present invention and its attendant advantages will be understood from this specification. While the above is a complete description of specific embodiments of the invention, the above description should not be taken as limiting the scope of the invention as defined by the claims.

What is claimed is:

1. A method of testing silicon wafers, said method comprising:
obtaining a first silicon wafer having a first plurality of dies;
obtaining a second silicon wafer having a second plurality of dies;
singulating said first plurality of dies from said first wafer so as to form a first set of singulated dies;
singulating said second plurality of dies from said second wafer so as to form a second set of singulated dies;
arranging said first set of singulated dies and said second set of singulated dies together on a support surface in a combined die arrangement, wherein said combined die arrangement comprises a total number of dies that exceeds the number of dies that were formed on said first silicon wafer;
testing said combined die arrangement as part of a single test sequence.

2. The method of testing silicon wafers as described in claim 1 wherein said combined die arrangement is comprised of all of the dies manufactured on said first silicon wafer and all of the dies manufactured on said second silicon wafer.

3. The method of testing silicon wafers as described in claim 1 wherein said testing said combined die arrangement comprises:
simultaneously coupling each die in said combined die arrangement with a testing device interface.

4. The method of testing silicon wafers as described in claim 1 wherein said testing said combined die arrangement comprises:
performing a single touchdown on said combined die arrangement with a testing device interface so as to accomplish a test of all dies in said combined die arrangement prior to removing said testing device interface.

5. The method of testing silicon wafers as described in claim 1 wherein said arranging said first set of singulated dies and said second set of singulated dies together comprises:
utilizing a robotically controlled transport device to place each singulated die on said support surface.

6. The method of testing silicon wafers as described in claim 1 and further comprising:
obtaining at least a third silicon wafer having a third plurality of dies;
singulating at least said third plurality of dies from said third wafer so as to form a third set of singulated dies;
arranging at least said third set of singulated dies as part of said combined die arrangement.

7. The method of testing silicon wafers as claimed in claim 1 wherein each of said dies in said first set of singulated dies and in said second set of singulated dies comprise a circuit configured as part of each die.

8. An apparatus for testing silicon wafers, said apparatus comprising:
a wafer singulating device configured to singulate a first wafer into singulated dies;
a die placement device configured to place said singulated dies from said first wafer into a singulated die testing arrangement;
wherein said wafer singulating device is further configured to singulate a second wafer into singulated dies;
wherein said die placement device is further configured to place said singulated dies from said second wafer into said singulated die testing arrangement;
a testing device interface configured to provide input and output signals to said singulated die testing arrangement.

9. The apparatus as claimed in claim 8 wherein said wafer singulating device comprises a scribing device for scribing said first and second silicon wafers.

10. The apparatus as claimed in claim 8 wherein said die placement device is configured to place all of said singulated dies from said first wafer into said singulated die testing arrangement.

11. The apparatus as claimed in claim 10 wherein said die placement device is configured to place all of said singulated dies from said second wafer into said singulated die testing arrangement.

12. The apparatus as claimed in claim 8 wherein said singulated die testing arrangement is comprised of all of the dies manufactured on said first wafer and all of the dies manufactured on said second wafer.

13. The apparatus as claimed in claim 8 wherein said testing device interface is configured to simultaneously couple with each die in said singulated die testing arrangement.

14. The apparatus as claimed in claim 8 wherein said testing device interface is configured to perform a single touchdown on said singulated die testing arrangement so as to accomplish a test of all dies in said singulated die testing arrangement prior to removing said testing device interface.

15. The apparatus as claimed in claim 8 wherein said die placement device comprises a robotically controlled transport device configured to place each die in said die testing arrangement.

16. The apparatus as claimed in claim 8 wherein said singulated die testing arrangement is sized with dies from at least three wafers.

17. The apparatus as claimed in claim 8 wherein each singulated die comprises a circuit.

18. An arrangement of singulated dies, said arrangement comprising:
a first set of singulated dies having been singulated from a first wafer;
a second set of singulated dies having been singulated from a second wafer;
said first set of singulated dies and said second set of singulated dies arranged in a combined die arrangement and wherein each singulated die is offset from the other singulated dies.

19. The arrangement of singulated dies as claimed in claim 18 wherein said first set of singulated dies includes all of the dies formed on a first wafer.

20. The arrangement of singulated dies as claimed in claim 18 wherein said combined die arrangement comprises all of the dies formed on a first wafer and all of the dies formed on a second wafer.

21. The arrangement of singulated dies as claimed in claim 18 wherein said combined die arrangement is configured to interface with a testing device interface so as to allow said testing device interface to interface with each die in the combined die arrangement in a single touchdown.

22. A testing device interface comprising:
a first interface configured to interface with a test computer;
a second interface configured to interface with a plurality of singulated dies;
wherein said singulated dies comprise singulated dies from a first wafer and from a second wafer arranged in a combined test pattern and wherein said second interface is configured to couple with all of the singulated dies in the combined test pattern simultaneously.
